(19) United States
(12) Patent Application Publication
(10) Pub. No.: US 2026/0331209 A1
(43) Pub. Date: Oct. 22, 2026

(54) APPARATUSES, SYSTEMS, AND METHODS FOR POOLED ERROR CORRECTION AMONG MULTIPLE MEMORY DEVICES

(71) Applicant: Micron Technology, Inc., Boise, ID (US)

(72) Inventors: Yang Lu, Boise, ID (US); Kang-Yong Kim, Boise, ID (US)

(73) Assignee: Micron Technology, Inc., Boise, ID (US)

(21) Appl. No.: 19/183,474

(22) Filed: Apr. 18, 2025

(51) Int. Cl. G11C 29/52; G11C 11/4096; G11C 29/02

(52) U.S. Cl. CPC G11C 29/52; G11C 11/4096; G11C 29/022

(57) ABSTRACT

A memory package includes multiple memory devices and an error correction circuit. The data and error correction bits for multiple of the memory devices are pooled together by the error correction circuit. For example, during read operations each memory device provides data, error correction bits or both to the error correction circuit. The error correction circuit uses the pooled data and error correction bits to perform error correction. Pooling the bits may allow for more efficient error correction, which may free up additional bits to be used for extra bits (e.g., metadata), telemetry information about the error correction, link protection, or combinations thereof.

### BACKGROUND

This disclosure relates generally to semiconductor devices, such as semiconductor memory devices. The semiconductor memory device may include a number of memory cells which are used to store information. The stored information may be encoded as binary data, and each memory cell may store a single bit of the information. Information may decay or change in the memory cells due to a variety of different errors, which may lead to one or more bits of incorrect information (e.g., bits with different states that the bit which was originally written) being stored in the memory device.

Memory devices may use various error correction schemes to repair information as it is read off the device. For example, an error correction code (ECC) circuit may generate parity bits when data is written to the device, and then use those parity bits to detect errors, correct errors, or both in the data when it is read out of the device. There may be a need to increase the efficiency of error correction schemes.

### BRIEF DESCRIPTION OF THE DRAWINGS

FIG. 1 is a block diagram of a semiconductor device according some embodiments of the present disclosure.

FIG. 2 is a block diagram of a memory system according to some embodiments of the present disclosure.

FIG. 3A-3E show different memory packages with pooled error correction according to some embodiments of the present disclosure.

FIG. 4 is a block diagram of a memory system 400 with chip kill error correction according to some embodiments of the present disclosure.

FIG. 5 is a memory system with multiple pooled error correction circuits according to some embodiments of the present disclosure.

FIG. 6 is a memory system where one memory device is shared between two error correction devices according to some embodiments of the present disclosure.

FIG. 7 is a block diagram of a memory system with pooled error correction according to some embodiments of the present disclosure.

FIG. 8 is a block diagram of a memory system with pooled error correction and increased telemetry information according to some embodiments of the present disclosure.

FIG. 9 is a block diagram of a pair of memory devices sharing an error correction circuit according to some embodiments of the present disclosure.

FIG. 10 is a block diagram of a pair of memory devices sharing an error correction circuit according to some embodiments of the present disclosure.

FIG. 11 is a block diagram of a memory device where two sub-channels share a error correction circuit according to some embodiments of the present disclosure.

FIG. 12 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device may include a memory array which has a number of memory cells, each located at the intersection of a word line (row) and digit line (column). During a read or write operation, a word line may be activated, and data may be read from, or written to, the memory cells along the activated word line. The memory device may implement an error correction scheme, for example by storing extra error correction information associated with the data. In an example error correction scheme, a codeword of data may have an associated set of parity bits. The codeword and its parity bits may be stored along a same word line. For example, a row may store one or more codewords, each of which includes J data bits, and also K parity bits for each of the codewords, which may be used to correct some number of the bits of the codeword. For example, in a single error correction (SEC) scheme, up to one bit of the codeword may be corrected.

In some memory devices, the ECC engine may be implemented on the memory device. During a write operation the parity bits may be generated by an error correction code (ECC) circuit based on the data written to the memory cells of the row. During a read operation the error correction code circuit may use the parity bits to determine if the read data bits are correct and may correct any errors which are found in the data as it is being provided off the memory device. In some memory systems, the error correction may be performed on a host device which operates a memory package. However, this may require a relatively large amount of error correction bits to be transferred back and forth between the host and the memory device(s).

The architecture of a memory device may generally determine the maximum number of data and parity bits which can be read out at one time. However, the efficiency of error correction schemes may generally increase as the number of data and parity bits increases. For example, if K parity bits can be used to correct one error in J data bits, then one error can generally be corrected in 2*J data bits with fewer than 2*K parity bits. Accordingly, it may be useful to pool data and parity across multiple devices. Performing the pooled error correction on the package may help reduce the number of bits which need to be transmitted between the host and the package.

The present disclosure is directed to apparatuses, systems, and methods for pooled error correction across multiple memory dies. A memory package includes two or more memory devices. The memory devices may be DRAM die packaged together, for example in a module, a package, a stacked memory device, a 3D memory device, or other configurations, or may be pseudo- or sub-channels within a single DRAM die. The package also includes an error correction circuit coupled to two or more of the memory devices. During an example read operation, each memory device provides a codeword and error correction bits (e.g., parity) to the error correction circuit. The error correction circuit performs error correction based on the pooled data codewords and the pooled error correction bits. The corrected data is provided to the controller. During a write operation, the controller provides data to the error correction circuit, which generates error correction bits based on the data, and then splits the data into codewords, and splits the parity to be stored on the individual memory devices.

Since the pooled error correction may generally be more efficient than error correction on the individual devices, the package may have extra bit capacity during read and write operations. For example, in an example implementation with only two devices, each of which provides J data bits, and can provide up to K parity bits, the pooled error correction circuit may repair one error in the 2J data bits using Y parity bits, where Y is less than 2K. Accordingly, there may be X extra bits where X = 2K – Y. Depending on various settings of the package, all or a portion of the extra bits may be unused, used for extra information such as metadata, used for increased error correction capability, or combinations thereof.

In some example embodiments, during read operations, the error correction circuit may generate error correction telemetry information. The telemetry may include information about the error correction, such as how many errors were detected, which device(s) the errors were located on, or other information. The telemetry information may be provided to the controller along with the corrected data. In some embodiments, the memory package may generate link protection bits which help ensure the fidelity of the connection between the host and the package.

In some embodiments, the architecture of the bus between the host and the memory package may be set up for error correction bits being passed back and forth (e.g., for host side error correction). In embodiments of the present disclosure, since the error correction bits stay on the package, the telemetry, link protection, or other extra bits (e.g., metadata) may take up space on the bus which otherwise would have been used for error correction bits, allowing the extra bits to be transmitted without changing the architecture. In some embodiments, fewer bits may be transmitted than the bus is capable of (e.g., there are fewer extra bits than there would have been error correction bits) which may lead to a power savings as fewer bits (and/or fewer data terminals) are used.

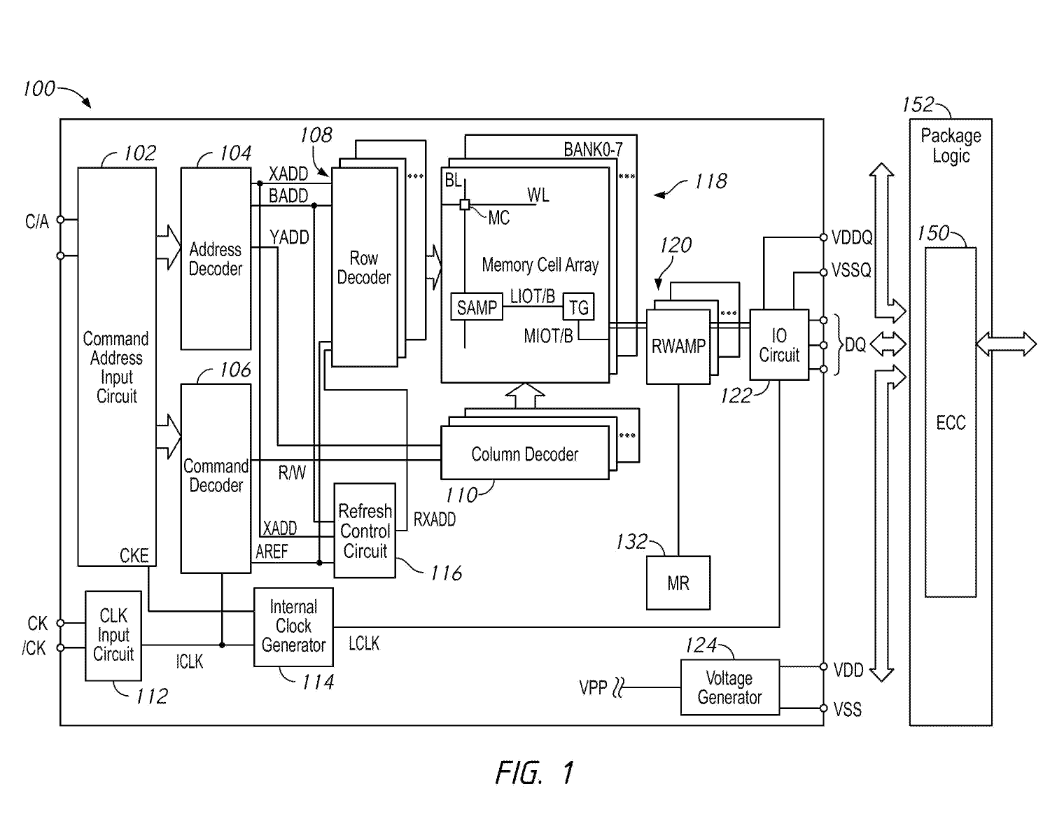

FIG. 1 is a block diagram of a memory device according an embodiment of the disclosure. The memory device 100 may be a semiconductor memory device, such as a DRAM device integrated on a single semiconductor chip. The memory device 100 may be one of several memory devices 100 on a package. The package includes a package logic circuit 152 such as a buffer shared in common with other memory devices such as the device 100. The package logic 152 includes an error correction circuit 150 that is shared by multiple memory devices such as the device 100.

The memory device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit line BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over complementary local data lines (LIOT/B), transfer gate (TG), and complementary main data lines (MIOT/B) which are coupled to the RWAMP circuit 120. Conversely, write data outputted from the RWAMP circuit 120 is transferred to the sense amplifier SAMP over the complementary main data lines MIOT/B, the transfer gate TG, and the complementary local data lines LIOT/B, and written in the memory cell MC coupled to the bit line BL.

The memory device 100 may employ a plurality of external terminals that include command and address (C/A) terminals coupled to a command and address bus to receive commands and addresses, and a CS signal, clock terminals to receive clocks CK and /CK, data terminals DQ to provide data, and power supply terminals to receive power supply potentials VDD, VSS, VDDQ, and VSSQ.

The clock terminals are supplied with external clocks CK and /CK that are provided to an input circuit 112. The external clocks may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a write command. The device 100 receives an activation command along with a bank address BADD and row address XADD along the C/A terminals. The device 100 then receives the write command along with a column address YADD. One or more of the commands may be shared in common with other devices of the package. As part of the write operation, the host provides data bits, and in some embodiments extra bits, to the error correction circuit 150. The error correction circuit 150 generates error correction bits based on the data (and extra bits) and then splits the data, error correction bits, and if applicable, extra bits into different portions. The memory device 100 receives its portion of data, error correction, extra bits (if applicable), or combinations thereof as write bits. As part of the activation, the row decoder 108 activates a word line based on the row address XADD in the bank indicated by BADD. The received write bits are written through the RWAMP 120 to memory cells at the intersection of the active word line and the columns indicated by YADD.

The device 100 may receive an access command which is a read command The device 100 receives an activation command along with a bank address BADD and row address XADD along the C/A terminals. The device 100 then receives the write command along with a column address YADD. One or more of the commands may be shared in common with other devices of the package. The device 100 activates the word line associated with XADD in the bank associated with BADD responsive to the activation command. Information, such as data, extra bits, error correction bits, or combinations thereof, is read out from the memory cells at the intersection of the active word line and the bit lines associated with YADD as read bits. The read bits are provided through the RWAMP 120 and IO circuits 122 along DQ terminals to the error correction circuit 150 along with read bits from other memory devices. The error correction circuit 150 uses the pooled read bits to form pooled read data, pooled read error correction bits, and if applicable pooled extra bits.

As part of the read operation, the error correction circuit 150 uses the pooled read error correction bits to correct, detect, or both, one or more bits in the pooled read data and if applicable the pooled read extra bits. The corrected pooled data (and pooled extra bits) is then sent on to the host or controller device which issued the read command. In some embodiments, the error correction circuit 150 may generate one or more telemetry bits as part of the read operation and provide those to the host along with the corrected pooled data (and corrected pooled extra bits). For example the telemetry bits may include information such as how many errors were detected/corrected, which device(s) the bits which were corrected/detected were on, other information about the error correction process or combinations thereof. In some embodiments, the package logic 152 may generate one or more link protection bits, such as CRC bits, which help to ensure the fidelity of information transmitted to the host.

The device 100 includes a settings register, such as a mode register 132. The mode register includes storage, organized in ‘registers’, which store information related to the operation of the memory. One or more registers (or portions thereof) may be used to control operations of the device 100 related to the pooled error correction. For example, the mode register 132 may include settings which determine if extra bits are used and if so how many. In another example, in some embodiments, the error correction circuit 150 may be located on the device 100, and the mode register 132 may be used to determine whether the error correction circuit 150 is enabled or not, since only one error correction circuit on a set of commonly coupled devices is used.

The device 100 may also receive commands causing it to carry out one or more refresh operations as part of a self-refresh mode. In some embodiments, the self-refresh mode command may be externally issued to the memory device 100. In some embodiments, the self-refresh mode command may be periodically generated by a component of the device. In some embodiments, when an external signal indicates a self-refresh entry command, the refresh signal AREF may also be activated. The refresh signal AREF may be a pulse signal which is activated when the command decoder 106 receives a signal which indicates entry to the self-refresh mode. The refresh signal AREF may be activated once immediately after command input, and thereafter may be cyclically activated at desired internal timing. The refresh signal AREF may be used to control the timing of refresh operations during the self-refresh mode. Thus, refresh operations may continue automatically. A self-refresh exit command may cause the automatic activation of the refresh signal AREF to stop and return to an IDLE state. The refresh signal AREF is supplied to the refresh control circuit 116. The refresh control circuit 116 supplies a refresh row address RXADD to the row decoder 108, which may refresh one or more wordlines WL indicated by the refresh row address RXADD.

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The internal potential VPP is mainly used in the row decoder 108, the internal potentials VOD and VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

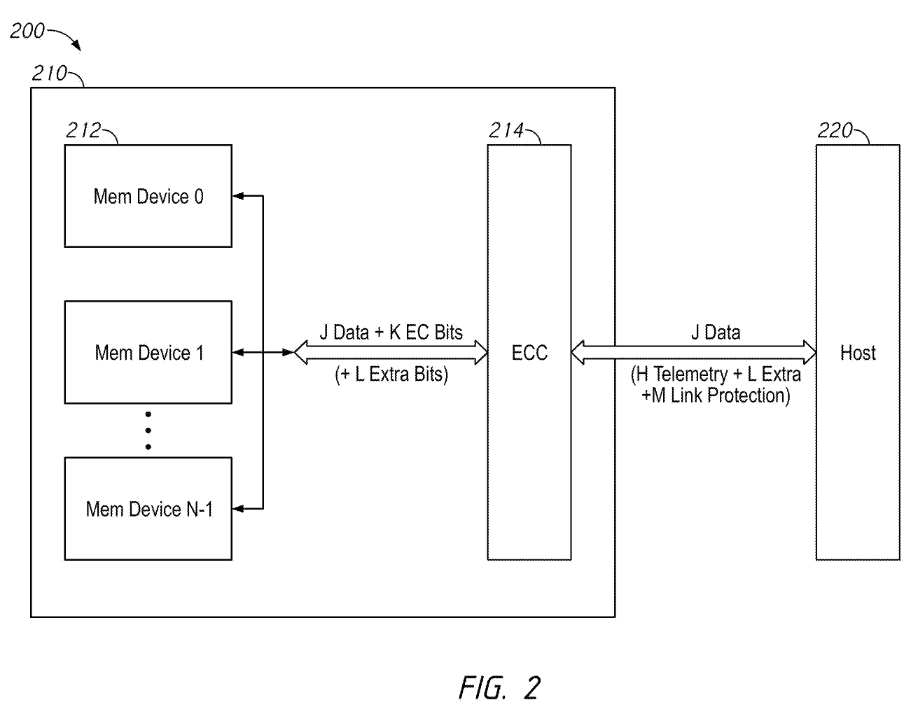

FIG. 2 is a block diagram of a memory system according to some embodiments of the present disclosure. The memory system 200 includes a memory package 210, which includes a number of memory devices 212 and an error correction circuit 214. The memory devices 212 may, in some embodiments, be implemented by the memory device 100 of FIG. 1, and the error correction circuit 214 may be implemented by the error correction circuit 150 of FIG. 1. The memory system 200 also includes a host 220, which operates the memory package 210, for example by providing commands and addresses along a command/address bus (not shown) as well as by sending and receiving data and other information to and from the memory package 210.

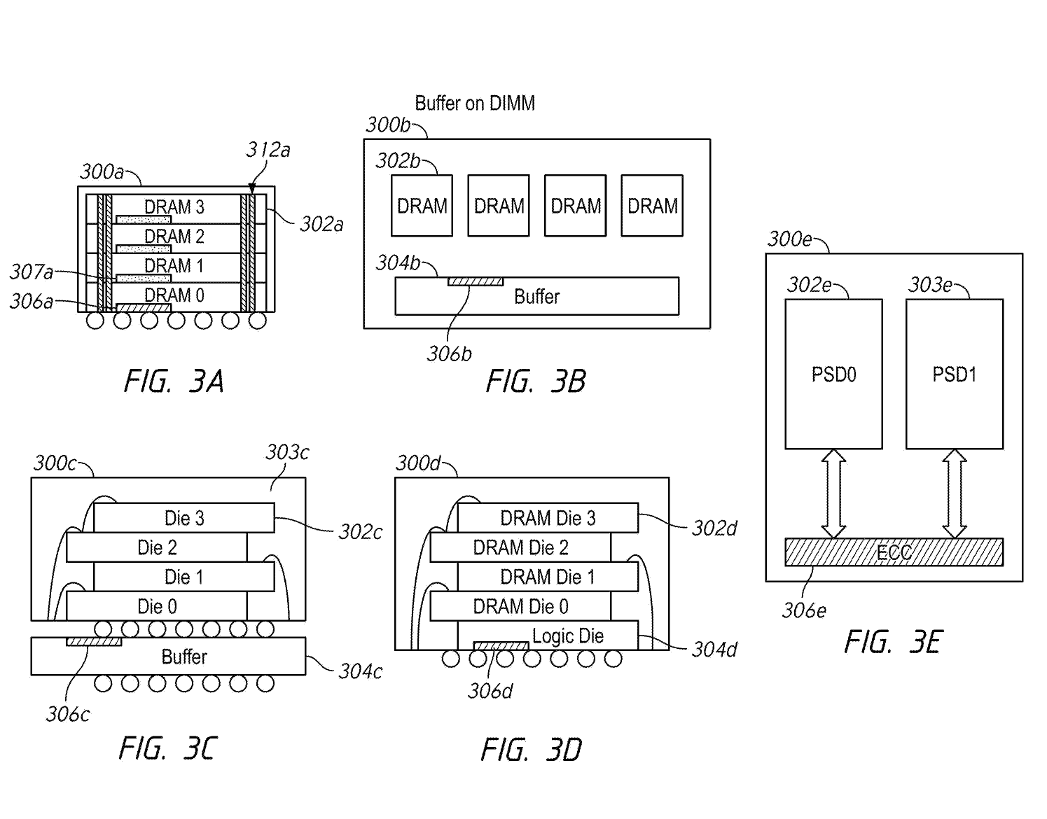

The example memory package 210 includes N memory devices. The memory devices may represent separate memory devices, such as different DRAM dies, or may represent sub-channels or pseudo-channels within a die. The error correction circuit 214 is shown as being separate from the memory devices 212. In some embodiments, the error correction circuit 214 may be included in a buffer, a logic die, an interface die or other logic common to the memory devices 212. In some embodiments, the error correction circuit 214 may be included in one of the memory devices 212. Different example arrangements of memory package 200 are described in more detail in FIGS. 3A-3E.

During a write operation, the host 220 provides commands and addresses along a command address bus (not shown) as well as J bits of data. The error correction circuit 214 generates K error correction bits based on the J bits of data. The error correction circuit 214 provides the J data bits and K parity bits to the memory devices 212. Each memory device 212 receives a portion of the J data bits and K parity bits. For example, in some embodiments, each device 212 may generally receive 1/N * (J+K) bits. In some embodiments, the data and error correction bits may be evenly divided, with each device 212 receiving a codeword of J/N data bits and K/N error correction bits. Other distributions may also be used. For example, some devices may be used to only store data while other devices may only store error correction bits. For example, if one device 212 is used to store the error correction bits, while the remaining devices store data bits, then one device 212 receives K error correction bits, while the other devices receive J/(N-1) data bits.

The error correction bits are generally referred to as parity bits herein, although other correction schemes may also be used. Similarly, error correction circuits are generally labelled as ‘ECC’ circuits herein, although other error correction schemes may also be used.

During a read operation, the host 220 sends commands and addresses over a command address bus (not shown). The memory devices 212 provide their respective portions of J data bits and K error correction bits to the error correction circuit 214. The error correction circuit 214 performs error correction based on the pooled data bits and error correction bits from the memory devices 212. In other words, the error correction circuit 214 may perform error correction on the J data bits based on the K error correction bits. The error correction circuit 214 provides the corrected J data to the host 220. The error correction bits are generally not transmitted as part of a read operation and thus remain entirely on the package 210.

In some embodiments the error correction circuit 214 may correct one or more bits of the data by flipping a state of a bit identified as being incorrect. In some embodiments, the error correction circuit may detect one or more bits of data without correcting them, for example by detecting a number of errors but not locating them to specific bits. In some embodiments, a mix of detection and correction may be performed.

In some embodiments, the error correction circuit may generate one or more telemetry bits during a read operation. The telemetry bits include information about the error correction. For example, the telemetry bits may include information such as how many errors were corrected, which device 212 stored the bit(s) which were corrected, or combinations thereof. In the example of FIG. 2, up to H telemetry bits may be generated.

In some embodiments, the host 220 may write and read one or more bits of extra information along with the data to the memory package 210. For example, the extra data may represent metadata. In such situations, the extra bits may be used along with the data bits to generate the parity bits during write operations, and then corrected during read operations. Similar to the error correction bits, the extra bits may be distributed in any fashion across the N memory devices. For example if there are L extra bits, then in some embodiments they may be evenly divided and each device 212 receives L/N extra bits. Other distributions may also be used.

In some embodiments, the package 200 may generate one or more link protection bits. The link protection bits may be generated by logic circuits of the package, such as in a buffer or other package logic (e.g., 152 of FIG. 1). The link protection bits may be used to ensure the fidelity of the information being sent from the package 210 to the host 220. In some embodiments, during write operations the host 220 may send link protection bits and the package 210 may use them to check the data. The link protection bits may be CRC bits in some embodiments. The link protection bits may pass back and forth between the package 210 and the host 220, but are not generally stored on the memory devices 212.

In an example implementation, during read and write operations, J data bits along with up to H telemetry bits, up to L extra bits, up to M link protection bits or combinations thereof may be transmitted between the package 210 and host 220. In some embodiments, any or all of the values H, L, and/or M may be zero. For example, telemetry and extra bits may be used but not link protection bits, or telemetry and link protection bits may be used but not extra bits, extra bits and link protection but not telemetry may be used, all three may be used, only one may be used, none may be used, etc. Similarly, the memory devices 212 between them store J data bits, K error protection bits and up to L extra bits. Any distribution may be used for the J data bits, K error protection bits, and up to L extra bits across the different memory devices.

In some embodiments, the architecture between the package 210 and the host 220 may be set up based on an expectation that the K error correction bits are transmitted between the package 210 and host 220. However, in the memory system 200, the K error protection bits stay on the package 210. This may free up to K bits worth of bandwidth between the package 210 and host 220. In some embodiments, the unused bandwidth may be used for additional bits. For example, if H + L + M is K or fewer bits, then the telemetry bits, extra bits, and/or link protection bits may be transmitted without changing the architecture of the bus. In some embodiments, the reduced bus between the package 210 and host 220 may be used for a power savings. For example, since fewer bits are driven than the expected K bits, there is a power savings compared to the expected transmission during read and write operations.

In some embodiments, each of the memory devices 212 also has an expected architecture for how many bits can be read or written during a single access operation. For example, each device 212 may be set up to access A data bits and B error correction bits in a single access operation, with A and B based on memory devices where error correction is performed on the device 212. However, the pooled error correction 214 may be more efficient than on-device error correction, and N*(A+B) may be a greater number than J+K, the total number of data and error correction bits used in an access operation of the package 210. In some embodiments, there may be a savings in power between the devices 212 and the error correction circuit 214 as fewer bits are transmitted than expected. In some embodiments, the difference between N*(A+B) and (J+K) may be at least partially taken up by the extra bits L.

In an example implementation where data, error correction, and extra bits are distributed evenly among the devices 212, each memory device may store J/N data bits, K/N error correction bits, and L/N extra bits. The package 210 may be set up so that J/N = A bits and (K+L)/N is less than or equal to B bits. In this manner, all of the information may be read or written on each memory device 212 in a single access pass.

In some example embodiments, the values A and B may be set based on an expectation of on-device 212 error correction where single error correction is performed. The pooling of data and error correction bits at the package level 210 may allow for greater than single error correction without changing the values A and B provided by the individual memory devices. For example, the error correction circuit 214 may implement double error correction, triple error correction, single error correction double error detection, or other schemes. Other error correction schemes (e.g., high error detection but no correction) may be used in other example embodiments.

FIG. 3A-3E show different memory packages with pooled error correction according to some embodiments of the present disclosure. The memory packages 300a of FIGS. 3A, 300b of FIGS. 3B, 300c of FIGS. 3C, 300d of FIG. 3D, and 300e of FIG. 3E, may, in some example embodiments, implement the memory package 200 of FIG. 2, and include one or more memory devices such as 100 of FIG. 1 and/or 210 of FIG. 2 along with one or more pooled ECC circuits such as 150 of FIG. 1 and/or 220 of FIG. 2. Each of the packages 300a-300d show four example memory devices, however more or fewer devices may be used in other example embodiments. The package 300e shows a memory chip with two sub-channels, however more or fewer sub-channels may be used in other example embodiments.

FIG. 3A shows a stacked memory package 300a. The stacked memory package 300a includes a number of individual memory devices 302a stacked on top of one another. For example, a first device DRAM 0 is at a bottom of the stack, a next device DRAM 1 is stacked on top of DRAM 0, a device DRAM 2 is stacked on top of DRAM 1 and so forth. The devices 302a are coupled together using one or more TSVs 312a. One of the devices 302a, in this example the bottom device DRAM 0, has an activated error correction circuit 306a. The error correction circuit 306a manages pooled data and error correction across the devices 302a. In the example of FIG. 3A, for manufacturing purposes, each of the devices 302a includes an error correction circuit, however only one error correction circuit 306a is activated, while the other error correction circuits 307a are inactivated.

FIG. 3B shows a memory module 300b. The memory module 300b includes memory devices 302b. The module 300b include module level logic such as a buffer 304b. Signals from the memory devices 302b, such as data, commands, and/or addresses, are passed through the buffer 304b before being coupled to/from a host device. The buffer 304b includes the pooled error correction circuit 306b.

FIG. 3C shows a stacked memory package 300c coupled to a buffer 304c. The package chip 303c includes a number of memory die 302c which are stacked on top of each other. Rather than the TSVs 312a of FIG. 3A, in the example package 300c, the different stacked die 302c are each coupled to pins along a bottom of a first chip 303c. That chip 303c couples to a second chip 304c, which acts as a buffer for the package 300c. The buffer 304c includes a error correction device 306c.

FIG. 3D shows a stacked memory package 300d with an integrated logic die 304d. The package 300d may be generally similar to the package 300c, except that the logic die 304d is integrated in the package 300d, rather than being a separate component as in the package 300c. The package 300d includes a number of memory devices 302d stacked on top of a logic die 304d, which includes the error correction circuit 306d.

FIG. 3E shows a single memory chip with two sub-channels 302e and 303e. The sub-channels 302e and 303e may represent portions of the chip 300e which can be operated independently or pseudo-independently from each other. For example, the first sub-channel 302e may include a first set of memory banks and the second sub-channel 303e may include a second set of memory banks. The two sub-channels 302e and 303e share an error correction circuit 306e. In some embodiments, certain signals, such as column select signals, command signals, address signals, or combinations thereof may be provided in common to both sub-channels 302e and 303e to make sure that both sub-channels 302e and 303e operate together to provide the pooled data and parity bits.

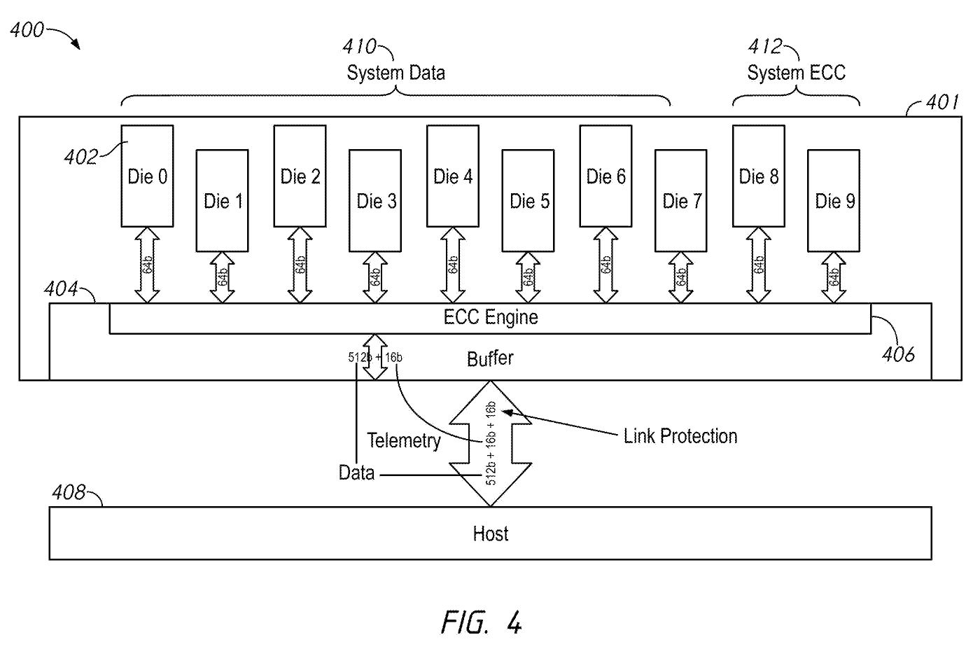

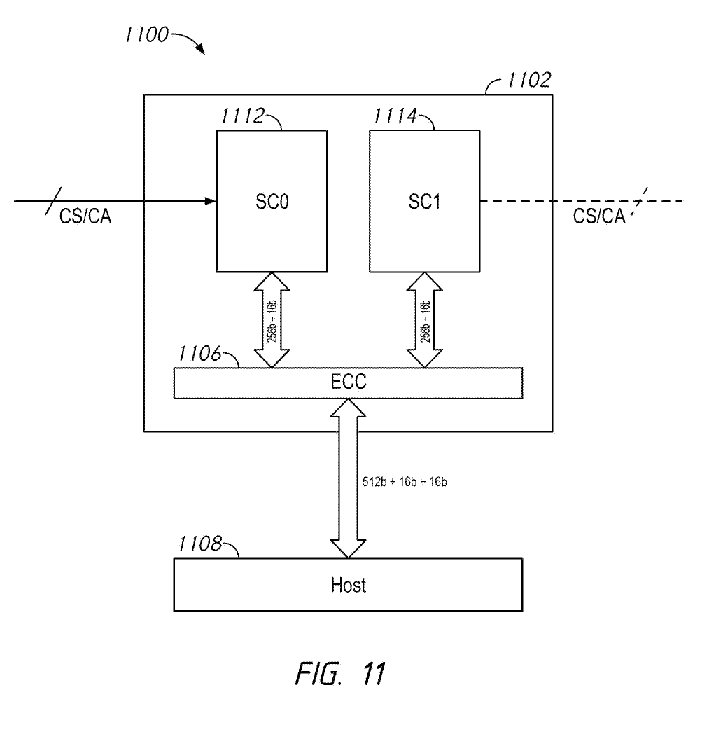

FIGS. 4-11 show different example pooled error correction implementations according to some embodiments of the present disclosure. FIGS. 4-11 show different example implementations to illustrate example ways in which pooled error correction may be used. For consistency, the examples of FIGS. 4-10 are generally drawn showing separate memory die and a buffer (e.g., similar to the package 300b of FIG. 3B). However, any of the example packages 300a to 300d of FIGS. 3A-3D may be used for any or all of the implementations of FIGS. 4-10. FIG. 11 shows an example implementation using sub-channels, similar to the package 300e of FIG. 3E.

Each of the FIGS. 4-11 is generally described with respect to certain example implementation details such as the number of bits per memory device, the number of error correction bits used to perform correction, the number of link protection bits, and other details. However, other numbers may be used in other example embodiments.

FIG. 4 is a block diagram of a memory system 400 with chip kill error correction according to some embodiments of the present disclosure. The memory system 400 includes a memory package 401 (e.g., 210 of FIG. 2, 300a of FIG. 3A, 300b of FIG. 3B, 300c of FIG. 3C, 300d of FIG. 3D) that includes 10 memory devices 402 (e.g., 100 of FIG. 1 and/or 210 of FIG. 2) and a buffer 404 with a pooled error correction circuit 406 (e.g., 150 of FIG. 1 and/or 214 of FIG. 2). The buffer is coupled to a host 408 (e.g., 220 of FIG. 2).

In the example of FIG. 4, there are 8 data die 410 used to store bits of data, and two error correction die 412 used to store error correction bits. During a read operation, each of the ten memory devices 402 provides 64 bits of information. The data die 410 each provide 64 bits of data for a total of 512 bits of data, and the error correction die 412 each provide 64 error correction bits for a total of 128 error correction bits. The error correction circuit 406 can use the 128 error correction bits to correct up to one memory die 402 worth of data. For example, if the data from Die 1 is corrupted, it can be corrected based on the 128 error correction bits. This may be referred to as a ‘chipkill’ error correction scheme, since one of the memory devices 402 can effectively be disabled without effecting the overall data.

In other chipkill schemes, the 512 data bits and 128 error correction bits are sent to the host device 408, where the host performs error correction. In the example 400 of the present disclosure, the error correction is performed on the memory package. This frees up a large number of bits that could be transmitted back and forth to the host 408 without diminishing the error correction capability. For example, with error correction performed on the memory package, there are up to 128 bits that could be transmitted back and forth in place of the error correction bits. In the example of FIG. 4, during a read operation, the error correction circuit 406 generates 16 bits of telemetry, and the buffer 404 generates 16 bits of link protection. The telemetry bits include information about the error correction that was performed, such as how many errors were detected, which device(s) 402 were the source of the error, or other information. The link protection bits help ensure proper transmission of the 512 corrected data bits and 16 telemetry bits to the host. These 32 extra bits may be used without a change to the architecture of the bus between the buffer 404 and the host 408 since the error correction bits are not being transmitted.

During an example write operation, the host 408 provides 512 data bits along with an optional 16 bits of link protection. The error correction circuit 406 uses the 512 data bits to generate 128 error correction bits. The 512 data bits are split into 8 portions of 64 bits each and written to respective ones of the data die 410. The 128 error correction bits are split into two portions of 64 bits each and written to the two die of the error correction die 412.

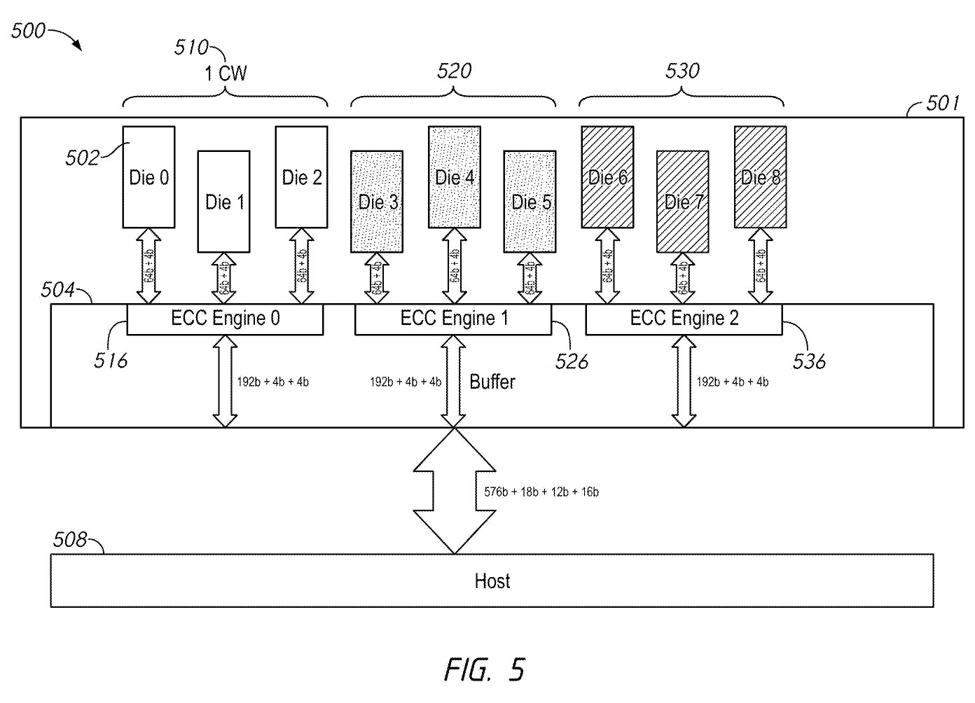

FIG. 5 is a memory system with multiple pooled error correction circuits according to some embodiments of the present disclosure. The memory system 500 of FIG. 5 includes a package 501 (e.g., 210 of FIG. 2, 300a of FIG. 3A, 300b of FIG. 3B, 300c of FIG. 3C, 300d of FIG. 3D) which includes nine memory devices 502 (e.g., 100 of FIG. 1 and/or 210 of FIG. 2) coupled to a common buffer 504. The buffer 504 is in communication with a host 508 (e.g., 220 of FIG. 2). The memory devices 502 are divided into three groups 510, 520 and 530 and the buffer 504 includes three error correction circuits 516, 526, and 536 (e.g., 150 of FIG. 1 and/or 214 of FIG. 2). The group 510 is coupled to error correction circuit 516, the group 520 is coupled to error correction circuit 526, and the group 530 is coupled to error correction 536.

During a read operation, each device 502 provides 64 data bits and 4 additional bits (e.g., A = 64 and B = 4). Accordingly, each error correction circuit 516, 526, and 536 receives a respective set of 192 data bits and up to 12 additional bits. In the example embodiment of FIG. 5, each error correction circuit 516, 526, and 536 performs single error correction, which uses 8 error correction bits for up to 255 data bits. Since each error correction circuit 516, 526, and 536 receives less than 255 data bits, only 8 of the 12 additional bits that each error correction circuit receives are needed for a single error correction scheme. One or more of the remaining four bits per device may be used as extra bits, for example as metadata bits, go unused, or be used for other purposes.

In the example of FIG. 5, each error correction circuit 516, 526, and 536 receives 192 data bits, 8 error correction bits, and 4 extra bits from the associated group 510, 520, or 530 respectively, of memory devices 502. Each error correction circuit performs single error correction on the 192 data bits and 4 extra bits and generates 4 telemetry bits based on the correction. The corrected data bits, extra bits, and the telemetry bits are pooled by the buffer for a total of 576 data bits, 12 extra bits, and 12 telemetry bits. The buffer 504 generates an additional 16 bits of link protection. The buffer 504 provides 576 bits of data, 12 extra bits, 12 telemetry bits, and 16 link protection bits to the host 508.

In an example read operation, the host 508 provides 576 data bits along with an optional 16 bits of link protection and an optional 12 extra bits. The buffer 504 splits the 576 data bits into three groups of 192 data bits each, and splits the extra bits into three groups of 4 bits each. Each error correction circuit 516, 526, and 536 generates 8 error protection bits based on the 192 data bits and 4 extra bits. The error correction circuits split the data, error protection bits, and extra bits among the associated 3 memory devices. For example, each device 502 in one of the sets 510, 520, or 530 may receive 64 data bits, two of the devices receive 4 error correction bits, and one device receives 4 extra bits.

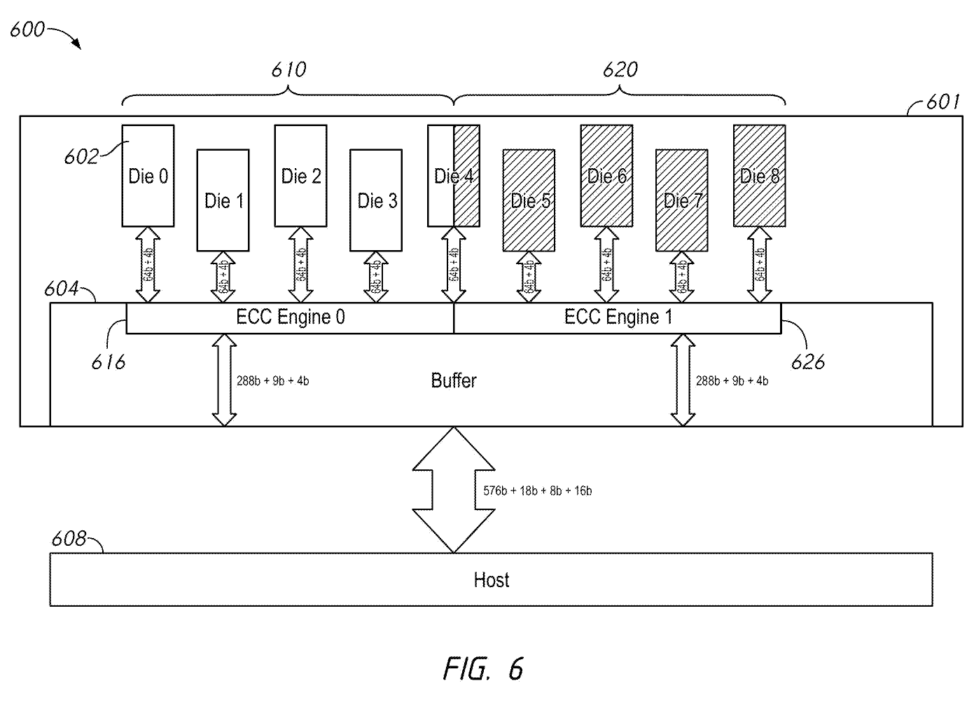

FIG. 6 is a memory system where one memory device is shared between two error correction devices according to some embodiments of the present disclosure. The memory system 600 includes a package 601 (e.g., 210 of FIG. 2, 300a of FIG. 3A, 300b of FIG. 3B, 300c of FIG. 3C, 300d of FIG. 3D) with 9 memory devices 602 (e.g., 100 of FIG. 1 and/or 210 of FIG. 2), similar to the system 500 of FIG. 5. In the memory system 600, the devices 602 are divided into two error correction groups 610 and 620. Since that doesn’t divide evenly among 9 devices 602, one device, in this case Die 4, is part of both groups 610 and 620. The four and a half devices 602 of the first group 610 are coupled to a first error correction circuit 616 in the buffer 604 and the four and a half devices 602 of the second group 620 are coupled to a second error correction circuit 626. The error correction circuits 616 and 626 (e.g., 150 of FIG. 1 and/or 214 of FIG. 2) are located in a buffer 604. The buffer 604 is coupled to a host device 608 (e.g., 220 of FIG. 2).

During a read operation, each device 602 provides 64 bits of data and four additional bits. The device 602 which is shared between groups provides half of its data and half of its additional bits to one error correction circuit 616 and half of its data and half of its additional bits to the other error correction circuit 626. In this implementation, Die 4 provides 32 data bits and 2 additional bits to each of the error correction circuits 616 and 626. Accordingly, the first error correction circuit 616 and the second error correction circuit 626 each receive 288 data bits and 18 additional bits from their respective groups 610 and 620. In this example implementation, each error correction circuit 616 and 626 uses 9 error correction bits to implement single error correction. This leaves 9 extra bits which can be used for other purposes, such as metadata. Accordingly, during a read operation, each error correction circuit 616 and 626 receives 288 data bits, 9 error correction bits, and up to 9 extra bits and corrects the data and extra bits. Each error correction circuit 616 and 626 performs error correction and generates 4 bits of telemetry. The corrected data and extra bits, as well as the telemetry are pooled by the buffer 604, which provides 576 data bits, 18 extra bits, 8 telemetry bits and 16 bits of link protection to the host 608.

During an example write operation, the host 608 provides 576 data bits, 18 extra bits, and 16 link protection bits. The buffer 604 splits the received information into halves, with 288 data bits and 9 extra bits going to each of the error correction circuits 616 and 626. Each error correction circuit 616 and 626 generates 9 error correction bits. Each error correction circuit 616 and 626 splits the resulting 288 data bits, 9 extra bits, and 9 error correction bits into 4 portions of 64 data bits and 4 extra bits and one portion of 32 data bits and 2 extra bits and routes them to the respective four and a half devices 602 of the respective groups 610 and 620.

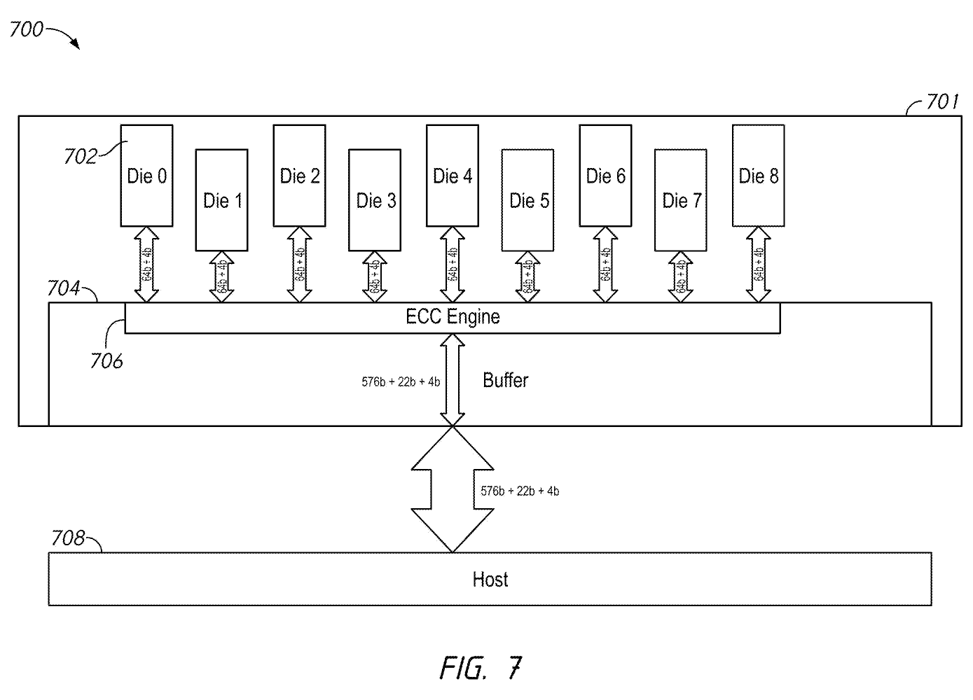

FIG. 7 is a block diagram of a memory system with pooled error correction according to some embodiments of the present disclosure. The memory system 700 includes a memory package 701(e.g., 210 of FIG. 2, 300a of FIG. 3A, 300b of FIG. 3B, 300c of FIG. 3C, 300d of FIG. 3D) which includes nine memory devices 702 (e.g., 100 of FIG. 1 and/or 210 of FIG. 2), similar to the system 500 of FIG. 5 and 600 of FIG. 6. In the memory system 700, the error correction is pooled across all nine of the devices 702 to an error correction circuit 706 (e.g., 150 of FIG. 1 and/or 214 of FIG. 2) in the buffer 704 of the package 701. The package is coupled to a host 708 (e.g., 220 of FIG. 2).

During an example read operation, each device 702 provides 64 bits of data and 4 additional bits. Accordingly, the error correction circuit 706 receives 576 data bits and 36 additional bits. Ten error correction bits are used in this example embodiment. Four of the other additional bits are unused, for a total of 22 extra bits. The error correction circuit 706 corrects the 576 data bits and 22 extra bits based on the 10 error correction bits. The error correction circuit 706 generates 4 telemetry bits. The buffer 704 provides the 576 corrected data bits and corrected extra bits along with the four telemetry bits to the host 708. Leaving four of the additional bit capacity unused allows room for the telemetry bits without expanding the 64+4 bit * 9 device bus between the buffer 704 and host 708.

During an example write operation, the host 708 provides 576 data bits along with 22 extra bits to the buffer 704. The error correction circuit 706 generates 10 error correction bits from the data bits and extra bits. The error correction circuit 706 then distributes the 576 data bits, 10 error correction bits, and 22 extra bits between the devices 702. One device 702 may only receive 64 data bits, or may receive 4 dummy bits, since the 32 error correction and extra bits do not divide evenly among nine devices.

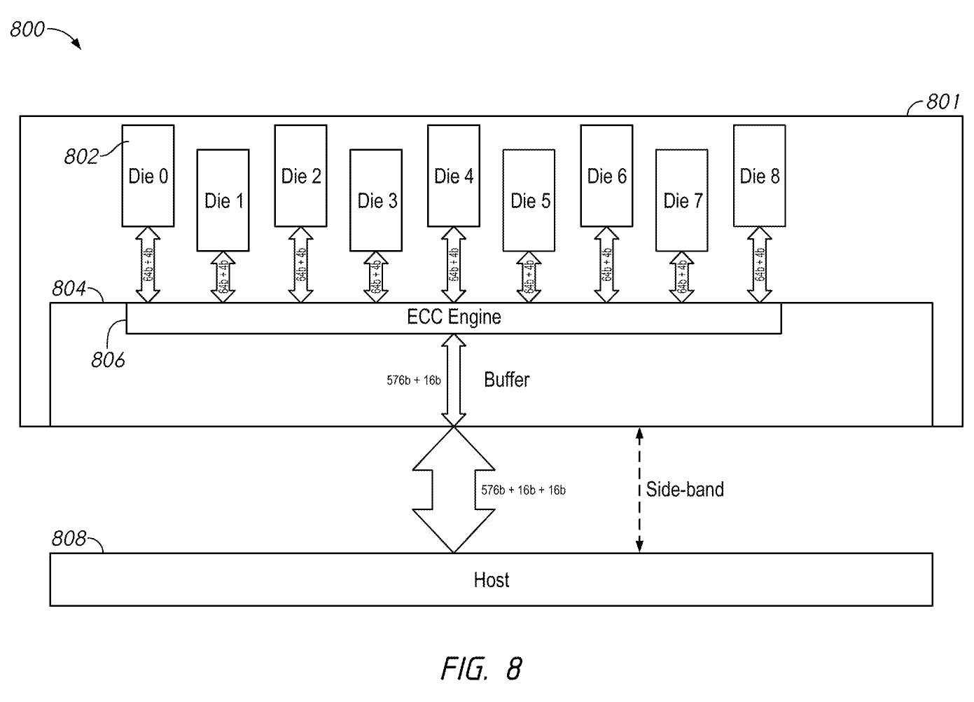

FIG. 8 is a block diagram of a memory system with pooled error correction and increased telemetry information according to some embodiments of the present disclosure. FIG. 8 shows a memory system 800 which is generally similar to the memory systems 500 of FIG. 5, 600 of FIG. 6, and 700 of FIG. 7. The memory system 800 includes a package 801 (e.g., 210 of FIG. 2, 300a of FIG. 3A, 300b of FIG. 3B, 300c of FIG. 3C, 300d of FIG. 3D) with nine devices 802 (e.g., 100 of FIG. 1 and/or 210 of FIG. 2) coupled to a buffer 804 with an error correction circuit 806 (e.g., 150 of FIG. 1 and/or 214 of FIG. 2). The buffer 804 is coupled to the host 808 (e.g., 220 of FIG. 2).

In contrast to the example of FIG. 7, in the example of FIG. 8, additional error correction bits are used to increase the number of bits which can be corrected by the error correction circuit 806. In the example of FIG. 8, twenty error correction bits are used (instead of 10 in FIG. 7). Since each device provides 4 additional bits and there are 9 devices 902, using 20 bits for error correction leaves up to 16 other bits which may be used as extra bits. The error correction circuit 806 performs corrections on the 576 data bits and 16 extra bits and generates 16 bits of telemetry. The buffer 804 provides 576 corrected data bits, sixteen corrected extra bits, sixteen telemetry bits and sixteen link protection bits. In some embodiments, some number of extra bits may be provided along the main bus (e.g., the DQ bus) and some number of the extra bits may be provided along a side-band such as an I3C bus.

During an example write operation, the host 808 provides 576 data bits, 16 extra bits, and 16 link protection bits. The extra bits may be sent along a main bus, a side bus, or both. The error correction circuit 806 generates 20 error correction bits from the 576 data bits and the 16 extra bits. The error correction circuit 806 splits the data, error correction, and extra bits among the devices 802.

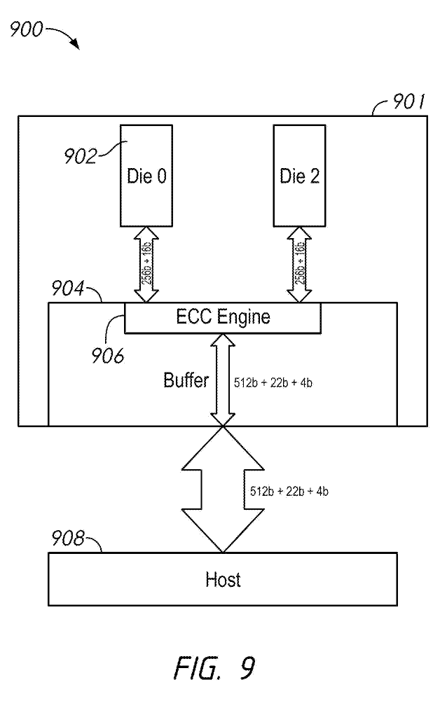

FIG. 9 is a block diagram of a pair of memory devices sharing an error correction circuit according to some embodiments of the present disclosure. In the embodiment of FIG. 9, the memory system 900 includes a package 901 (e.g., 210 of FIG. 2, 300a of FIG. 3A, 300b of FIG. 3B, 300c of FIG. 3C, 300d of FIG. 3D) which includes two memory devices 902 (e.g., 100 of FIG. 1 and/or 210 of FIG. 2) coupled to a pooled error correction circuit 906 (e.g., 150 of FIG. 1 and/or 214 of FIG. 2) in a buffer 904. The buffer is coupled to a host 908 (e.g., 220 of FIG. 2).

During an example read operation, each memory device 902 provides 256 data bits and up to 16 additional bits. The error correction circuit 906 receives 512 data bits and up to 32 additional bits. To perform single error correction on 512 data bits, 10 error correction bits are used. In the example of FIG. 9, 10 of the additional bits are used as error correction bits, and the 22 remaining bits are used as extra bits. The error correction circuit 906 corrects the 512 data bits and 22 extra bits based on the 10 error correction bits. The error correction circuit 906 generates four bits of telemetry information. The buffer 904 provides 512 corrected data bits, 22 corrected extra bits, and four bits of telemetry to the host. While not shown in FIG. 9, link protection bits may also be provided from the buffer 904 to the host 908.

During an example write operation, the host 908 provides 512 data bits and 22 extra bits (along with optional link protection bits, not shown). The error correction circuit 906 generates 10 error correction bits based on the 512 data bits and 22 extra bits. The error correction circuit 906 splits the data, extra bits, and error correction bits between the two devices 902.

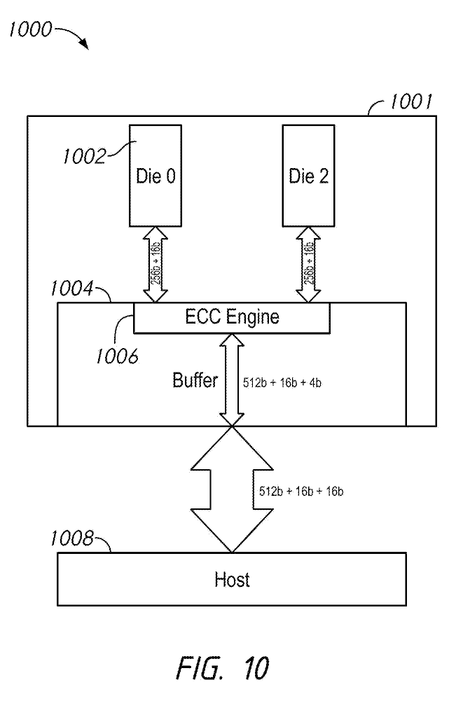

FIG. 10 is a block diagram of a pair of memory devices sharing an error correction circuit according to some embodiments of the present disclosure. In the embodiment of FIG. 10, the memory system 1000 includes a package 1001 (e.g., 210 of FIG. 2, 300a of FIG. 3A, 300b of FIG. 3B, 300c of FIG. 3C, 300d of FIG. 3D) which includes two memory devices 1002 (e.g., 100 of FIG. 1 and/or 210 of FIG. 2) coupled to a pooled error correction circuit 1006 (e.g., 150 of FIG. 1 and/or 214 of FIG. 2) in a buffer 1004. The buffer is coupled to a host 1008 (e.g., 220 of FIG. 2).

The example of FIG. 10 may be largely similar to the example of FIG. 9, but in FIG. 10, the memory package 1000 uses increased error protection. In an example read operation, each device 1002 provides 256 data bits and up to 16 additional bits. The error correction circuit 1006 uses 16 error correction bits to perform error correction. The error correction circuit 1006 may perform error correction and/or detection on more bits than the error correction circuit 906 of FIG. 9. Since more of the additional bits are used for error correction, there are 16 extra bits (compared to 22 in the example of FIG. 9). The error correction circuit also generates 4 telemetry bits. The buffer provides the corrected 512 data bits, up to 16 corrected extra bits, and the four telemetry bits along with 12 bits of link protection.

During an example read operation, the host 1008 provides 512 data bits, 16 extra bits and 12 link protection bits. The error correction circuit 1006 generates 16 error correction bits based on the 512 data bits and the 16 extra bits. The error correction circuit 1006 divides the data, extra bits and error correction bits between the two devices 1002.

FIG. 11 is a block diagram of a memory device where two sub-channels share a error correction circuit according to some embodiments of the present disclosure. The memory system 1100 includes a memory die 1102 (e.g., 200 of FIG. 2 and/or 300e of FIG. 3E) and a host 1108 (e.g., 220 of FIG. 2). The memory die 1102 may, in some embodiments, represent a single memory chip such as 300e of FIG. 3E. The memory die 1102 includes two sub-channels 1112 and 1114, which are coupled to a pooled error correction circuit 1106 (e.g., 150 of FIG. 1 and/or 214 of FIG. 2). The sub-channels 1112 and 1114 may act in an analogous way to the memory devices (e.g., 100 of FIG. 1 and/or 210 of FIG. 2) of the previous examples. The sub-channels 1112 and 1114 may each represent multiple banks of a memory die 1102 and may act semi-independently of each other.

In the example of FIG. 11, during a read operation each sub-channel 1112 and 1114 provides 256 bits of data and up to 16 additional bits. Sixteen of the additional bits are used as error protection bits, which leaves 16 extra bits which can be used for other purposes. The die 1102 also generates 4 bits of telemetry and 12 bits of linked protection. The die 1102 provides the corrected 512 data bits and up to 16 corrected extra bits as well as 4 telemetry bits and 12 link protection bits. In this way, the host 1108 receives 512 data bits plus 32 other bits, however, by pooling the error correction, some of the other bits are freed up for other purposes such as extra bits, telemetry bits, and link protection bits.

In some embodiments, since the two sub-channels 1112 and 1114 operate together for the purposes of the pooled error correction, they may both share signals such as column select signals CS or command/address signals CA.

In an example write operation, the host 1108 provides 512 data bits, 16 extra bits, and 16 bits of link protection to the die 1102. The error correction circuit generates 16 error correction bits from the 512 data bits and 16 extra bits. The data, error correction, and extra bits are divided between the two sub-channels 1112 and 1114.

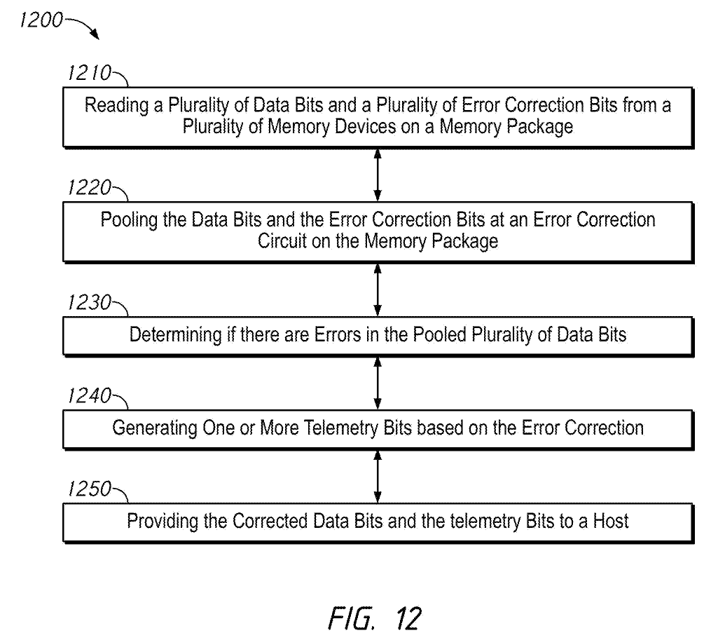

FIG. 12 is a flow chart of a method according to some embodiments of the present disclosure. The method 1200 may, in some embodiments, be performed by one or more of the memory packages described herein, such as the memory package 200 of FIG. 2, any of 300a-300e of FIGS. 3A-3E, 400 of FIG. 4, 500 of FIG. 5, 600 of FIG. 6, 700 of FIG. 7, 800 of FIG. 8, 900 of FIG. 9, 1000 of FIG. 10, and/or 1100 of FIG. 11. The method 1200 represents a method of performing a read operation on a memory package.

The method 1200 begins with box 1210 which describes reading a plurality of data bits and a plurality of error correction bits from a plurality of memory devices (e.g., 100 of FIG. 1 and/or 212 of FIG. 2) on a memory package. The method 1200 may include receiving a read command from a host device (e.g., 220 of FIG. 2). In some embodiments, the method 1200 may include reading data bits and error correction bits from each of the plurality of memory devices. In some embodiments, the method 1200 may include reading data bits from some memory devices and error correction bits from other memory devices.

Box 1210 may be followed by box 1220 which describes pooling the data bits and the error correction bits from the memory devices at an error correction circuit (e.g., 150 of FIG. 1 and/or 214 of FIG. 2) on the memory package. For example the method 1200 may include the error correction circuit receiving a set of bits from the plurality of memory devices, where the set of bits include the data bits and the error correction bits.

Box 1220 may be followed by box 1230, which describes determining if there are errors in the pooled plurality of data bits based on the pooled error correction bits with the error correction circuit. For example, box 1230 may include detecting one or more errors, correcting one or more errors, or combinations thereof.

Box 1230 may be followed by box 1240, which describes generating one or more telemetry bits based on the error correction with the error correction circuit. For example, the telemetry bits may indicate information about the error correction such as if errors were corrected, how many errors were corrected, if errors were detected, how many errors were detected, which memory device(s) provided the bits where the errors were corrected/detected, or combinations thereof.

Box 1240 may be followed by box 1250, which describes providing the corrected data bits and the telemetry bits to a host. For example, the method 1200 may include providing the corrected data bits and the telemetry bits along a data bus. In some embodiments, the method 1200 may include generating one or more telemetry bits and providing the telemetry bits to the host. In some embodiments, the method 1200 may include reading the plurality of data bits and the plurality of error correction bits as part of a single access pass of the memory devices.

In some embodiments, the method 1200 may include reading a second plurality of data bits and a second plurality of error correction bits from a second plurality of memory devices on the memory package, pooling the second plurality of data bits and the second plurality of error correction bits at a second error correction circuit on the memory package, determining if there are errors in the pooled second plurality of data bits based on the second plurality of error correction bits with the second error correction circuit and providing the second plurality of corrected error bits to the host. In some embodiments, there may be an additional memory device which provides bits to both the first and the second error correction circuits. For example, the method 1200 may include directing a first portion of the plurality of bits to the first error correction device as a portion of the plurality of data bits, a portion of the plurality of error correction bits or a combination thereof and directing a second portion of the plurality of bits to the second error correction device as a portion of the second plurality of data bits, a portion of the second plurality of error correction bits, or a combination thereof.

In some embodiments, the method 1200 may include reading a plurality of extra bits from the plurality of memory devices as part of the read operation, pooling the plurality of extra bits at the error correction circuit, determining if there are errors in the plurality of extra bits based on the plurality of error correction bits with the error correction circuit, and providing the corrected extra bits along with the corrected data bits and the telemetry bits to the host device.

In some embodiments, a similar method may be used to perform a write operation. In an example write operation method, the write includes receiving pooled data bits along with optional extra bits and optional link protection bits from a host device. The method includes generating pooled error correction bits based on the pooled data bits and optional extra bits with the error correction circuit. The method includes splitting the pooled data, pooled error correction bits, and optional extra bits into a plurality of portions and writing each portion to one of the plurality of memory devices.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. A memory package comprising:
a plurality of memory devices configured to provide a plurality of data bits and a plurality of error correction bits during a read operation;
an error correction circuit coupled to the plurality of memory devices and configured to determine if there are errors in the plurality of data bits based on the plurality of error correction bits, wherein the error correction circuit is configured to generate one or more telemetry bits based on the error correction, and wherein the memory package is configured to provide the corrected data bits and the telemetry bits to a host device as part of the read operation.

2. The memory package of claim 1, wherein the plurality of memory devices are configured to provide a plurality of extra bits during the read operation,
wherein the error correction circuit is configured to determine if there are errors in the plurality of data bits and the plurality of extra bits, and
wherein the memory package is configured to provide the corrected data bits the telemetry bits, and the corrected extra bits to the host device as part of the read operation.

3. The memory package of claim 2, wherein the extra bits include metadata bits.

4. The memory package of claim 2, wherein each of the memory devices provides data, error correction, extra, or combination thereof as part of a single access pass.

5. The memory package of claim 1, wherein the memory package is configured to generate one or more link protection bits, and wherein the memory package is configured to provide the corrected data bits, the telemetry bits, and the link protection bits to the host device as part of the read operation.

6. The memory package of claim 1, wherein the memory package is a stacked memory package.

7. The memory package of claim 1, wherein the error correction circuit is located in one of the plurality of memory devices.

8. The memory package of claim 1, wherein the memory package is a memory chip, and the first memory device is a first sub-channel of the memory chip and the second memory device is a second sub-channel of the memory chip.

9. The memory package of claim 1, further comprising:
a second plurality of memory devices configured to provide a second plurality of data bits and a second plurality of error correction bits;
a second error correction circuit coupled to the second plurality of memory devices and configured to determine if there are errors in the second plurality of data bits based on the second plurality of error correction bits, wherein the second error correction circuit is configured to generate one or more second telemetry bits based on the error correction, and wherein the memory package is configured to provide the second corrected data bits and the second telemetry bits to the host device as part of the read operation.

10. The memory package of claim 9, further comprising an additional memory device coupled to the first error correction circuit and the second error correction circuit, wherein the additional memory device is configured to provide bits to the first error correction circuit and bits to the second error correction circuit as part of the read operation.

11. A system comprising:
a host device configured to send a read command as part of a read operation
a memory package comprising:
a plurality of memory devices configured to provide a plurality of data bits and a plurality of error correction bits responsive to the read command;
an error correction circuit coupled to the plurality of memory devices and configured to determine if there are errors in the plurality of data bits based on the plurality of error correction bits, and generate one or more telemetry bits based on the error correction,
wherein the memory package is configured to provide the corrected data bits and the telemetry bits to the host device as part of the read operation.

12. The system of claim 11, further comprising a data bus coupling the memory package to the host device,
wherein the memory package is configured to provide the corrected data bits and the telemetry bits along a data bus.

13. The system of claim 11, further comprising:
a data bus coupling the memory package to the host device; and
a side band channel coupling the memory package to the host device,
wherein the memory package is configured to provide the corrected data bits along the data bus and provide the telemetry bits along the side band channel.

14. The system of claim 11, wherein the memory package is configured to generate one or more link protection bits and provide the corrected data bits, the telemetry bits and the link protection bits to the host device as part of the read operation.

15. The system of claim 11, wherein the plurality of memory devices are configured to provide a plurality of extra bits during the read operation,
wherein the error correction circuit is configured to determine if there are errors in the plurality of data bits and the plurality of extra bits, and
wherein the memory package is configured to provide the corrected data bits the telemetry bits, and the corrected extra bits to the host device as part of the read operation.

16. A method comprising:
reading a plurality of data bits and a plurality of error correction bits from a plurality of memory devices on a memory package as part of a read operation;
pooling the plurality of data bits and the plurality of error correction bits at an error correction circuit on the memory package;
determining if there are errors in the plurality of data bits based on the plurality of error correction bits with the error correction circuit;
generating one or more telemetry bits based on the error correction; and
providing the corrected data bits and the telemetry bits to a host device.

17. The method of claim 16, further comprising:
reading a second plurality of data bits and a second plurality of error correction bits from a second plurality of memory devices on the memory package as part of the read operation;
pooling the second plurality of data bits and the second plurality of error correction bits at a second error correction circuit on the memory package;
determining if there are errors in the second plurality of data bits based on the second plurality of error correction bits with the second error correction circuit;
generating one or more second telemetry bits based on the error correction of the second plurality of data bits; and
providing the corrected second plurality of data bits and the second telemetry bits to the host device.

18. The method of claim 17, further comprising:
reading a plurality of bits from an additional device as part of the read operation;
directing a first portion of the plurality of bits to the first error correction device as a portion of the plurality of data bits, a portion of the plurality of error correction bits or a combination thereof; and
directing a second portion of the plurality of bits to the second error correction device as a portion of the second plurality of data bits, a portion of the second plurality of error correction bits, or a combination thereof.

19. The method of claim 16, further comprising reading the plurality of data bits and the plurality of error correction bits as part of a single access pass of the plurality of memory devices.

20. The method of claim 16, further comprising:
reading a plurality of extra bits from the plurality of memory devices as part of the read operation;
pooling the plurality of extra bits at the error correction circuit;
determining if there are errors in the plurality of extra bits based on the plurality of error correction bits with the error correction circuit; and
providing the corrected extra bits along with the corrected data bits and the telemetry bits to the host device.
